(19) United States
(12) Patent Application Publication
(10) Pub. No.: US 2003/0116795 A1
(43) Pub. Date: Jun. 26, 2003

(54) Method of manufacturing a tantalum pentaoxide - aluminum oxide film and semiconductor device using the film

(76) Inventor: Kwang Chul Joo, Yongin-Shi (KR)

Correspondence Address: Law Offices, Jacobson Holman, Professional Limited Liability Company, 400 Seventh Street, N.W., Washington, DC, 20004-2218, US

(21) Appl. No.: 10/286,976

(22) Filed: Nov. 4, 2002

(30) Foreign Application Priority Data
Dec. 22, 2001 (KR) 2001-83497

(51) Int. Cl. H01L 21/8242; H01L 27/108; H01L 29/76; H01L 31/119

(52) U.S. Cl. 257/296; 438/785; 438/778; 438/240; 257/310

(57) ABSTRACT

The present invention relates to a method of manufacturing a TA₂O₅—AL₂O₃ film and a semiconductor device using the film. Chemical vapor of a Ta component, chemical vapor of an Al component and an excess O₂ gas are surface-chemical-reacted within a LPCVD chamber to form a (Ta₂O₅)_{1-X}—(Al₂O₃)_{X} film of an amorphous state on a substrate. The (Ta₂O₅)_{1-X}—(Al₂O₃)_{X} film of the amorphous state is annealed to form a (Ta₂O₅)_{1-X}—(Al₂O₃)_{X} film of a crystal state that has a high dielectric constant and a stable stoichiometry compared to an existing Ta₂O₅ film. At this time, the crystal (Ta₂O₅)_{1-X}—(Al₂O₃)_{X} is applied to the semiconductor device.

### BACKGROUND OF THE INVENTION

1. Field of the Invention

The invention relates generally to a method of manufacturing a tantalum pentaoxide-aluminum oxide (TA₂O₅—AL₂O₃) film and a semiconductor device using the film, and more particularly to, a method of manufacturing a (Ta₂O₅)_{1-X}—(Al₂O₃)_{X} film having a high dielectric constant and a stable stoichiometry and a semiconductor device using the film.

2. Description of the Prior Art

Generally, a cell transistor in a flash memory device being a nonvolatile memory device usually has an oxide-nitride-oxide (ONO) structure as a dielectric film between a floating gate and a control gate. The floating gate employs a polysilicon layer that is over-etched. When an underlying oxide film of the ONO structure is grown on the floating gate by means of a thermal oxidization method, the characteristic of the ONO dielectric film is degraded due to an impurity component of a high concentration since the defect intensity of the ONO dielectric film is high. Further, it is difficult to reduce the thickness of the ONO dielectric film since the thickness of the oxide film is not uniform. Due to this, the ONO dielectric film has a limitation in securing a charge capacity necessary for a next-generation flash memory product.

In order to overcome these problems, a research has been made by which a Ta₂O₅ film used in a DRAM product of over 256M level is applied to the dielectric film of the flash memory device.

However, as the Ta₂O₅ film has an unstable stoichiometry, a substitution Ta atom caused by the difference in the composition ratio of Ta and O, that is, an oxygen vacancy atom exist within the Ta₂O₅ film. As the Ta₂O₅ film itself has an unstable chemical composition, the substitution Ta atom of the oxygen vacancy state inevitably exist locally within the film always. Therefore, in order to stabilize the unstable stoichiometry native to the Ta₂O₅ film to prevent the leakage current, it is required an additional oxidization process for oxidizing the substitution Ta atom that exists within the film. Also, when the film is formed, carbon compositions such as C, CH₄, C₂H₄, etc. and water (H₂O), which are impurities, also exist due to reaction of an organic matter of Ta(OC₂H₅)₅ being a precursor of the Ta₂O₅ film with O₂ gas or N₂O gas. As a result, there are possibilities that the leakage current from the floating gate of the cell transistor to the dielectric film is increased and the dielectric characteristics is also degraded, due to carbon, ion and radical that exist within the Ta₂O₅ film as an impurity. Due to the above reasons, there are several problems that must be overcome in order to use the Ta₂O₅ film as the dielectric film of the cell transistor in the flash memory device being the nonvolatile memory device.

### SUMMARY OF THE INVENTION

The present invention is contrived to solve the above problems and an object of the present invention is to provide a method of manufacturing a (Ta₂O₅)_{1-X}—(Al₂O₃)_{X} film having a higher dielectric constant than a Ta₂O₅ film while solving problems in the conventional Ta₂O₅ film.

Another object of the present invention is to improve an electrical characteristic and reliability of a cell transistor and to implement a next-generation flash memory, by applying the (Ta₂O₅)_{1-X}—(Al₂O₃)_{X} film having a high dielectric constant and a stable stoichiometry to a cell transistor of a flash memory.

Still another object of the present invention is to improve an electrical characteristic and reliability of the device and to implement a higher level of integration in the device, by employing the (Ta₂O₅)_{1-X}—(Al₂O₃)_{X} film having a high dielectric constant and a stable stoichiometry instead of the Ta₂O₅ film used in the capacitor of the DRAM or the transistor of the DRAM.

In order to accomplish the above object, a method of manufacturing a tantalum pentaoxide-aluminum oxide (TA₂O₅—AL₂O₃) film according to the present invention comprises the steps of forming a lower layer, forming an amorphous (Ta₂O₅)_{1-X}—(Al₂O₃)_{X} film on the lower layer using chemical vapor of Ta component, chemical vapor of Al component and excess O₂ gas, and annealing the amorphous (Ta₂O₅)_{1-X}—(Al₂O₃)_{X} film to form a crystal (Ta₂O₅)_{1-X}—(Al₂O₃)_{X} film.

In the above, the method further comprises the step of, before the amorphous (Ta₂O₅)_{1-X}—(Al₂O₃)_{X} film is formed, performing nitrification treatment on the surface of the lower layer, and cleaning the nitrification treated lower layer. Among the above steps, one of the nitrification treatment step and the nitride film formation step may be omitted.

In the above, the chemical vapor of the Ta component is obtained by evaporating a Ta precursor of a given amount supplied to an evaporator or an evaporating tube through a flow controller such as a mass flow controller (MFC). The chemical vapor of the Al component is obtained by evaporating a Al precursor of a given amount supplied to the evaporator or the evaporating tube through the flow controller such as the mass flow controller (MFC). The amorphous (Ta₂O₅)_{1-X}—(Al₂O₃)_{X} film is formed by introducing a surface chemical reaction within a low pressure chemical vapor deposition (LPCVD) chamber under an excess O₂ gas being a reaction gas at the mole ratio of Al/Ta=0.01˜0.5 in the chemical vapor of the Ta component and the chemical vapor of the Al component.

In the above, the annealing process includes sequentially performing a low temperature annealing process and a high temperature annealing process. The low temperature annealing process is performed in order to oxidize the substitution Ta atom being an oxygen vacancy atom and carbon compositions such as C, CH₄, C₂H₄, etc. being a reaction byproduct, which exist within the amorphous (Ta₂O₅)_{1-X}—(Al₂O₃)_{X} film and to strengthen the coupling force, so that an unstable stoichiometry of the Ta₂O₅ film can be stabilized. The high temperature annealing process is performed in order to remove an impurity such as a carbon composition existing within the amorphous (Ta₂O₅)_{1-X}—(Al₂O₃)_{X} film and to crystalline the amorphous (Ta₂O₅)_{1-X}—(Al₂O₃)_{X} film.

Further, in a semiconductor device of the present invention for accomplishing the above objects, the (Ta₂O₅)_{1-X}—(Al₂O₃)_{X} film is used as a dielectric film or a gate insulating film, in a cell transistor of a flash memory having a structure in which the dielectric film is formed between the floating gate being a lower layer and a control gate being an upper layer, a transistor of a DRAM having a structure in which a gate insulating film is formed between a semiconductor substrate being the lower layer and a gate electrode being the upper layer, and a capacitor of the DRAM having a structure in which a dielectric film is formed between a lower electrode being the lower layer and an upper electrode being the upper layer.

### BRIEF DESCRIPTION OF THE DRAWINGS

The aforementioned aspects and other features of the present invention will be explained in the following description, taken in conjunction with the accompanying drawings, wherein:

FIG. 1˜FIG. 7 are cross-sectional views of semiconductor devices for describing a method of manufacturing a tantalum pentaoxide-aluminum oxide (TA₂O₅—AL₂O₃) film according to a preferred embodiment of the present invention; and

FIG. 8 is a cross-sectional view of a semiconductor device for describing the semiconductor device to which a TA₂O₅—AL₂O₃ film manufactured by the method of the present invention is applied.

### DETAILED DESCRIPTION OF PREFERRED EMBODIMENTS

The present invention will be described in detail by way of a preferred embodiment with reference to accompanying drawings, in which like reference numerals are used to identify the same or similar parts.

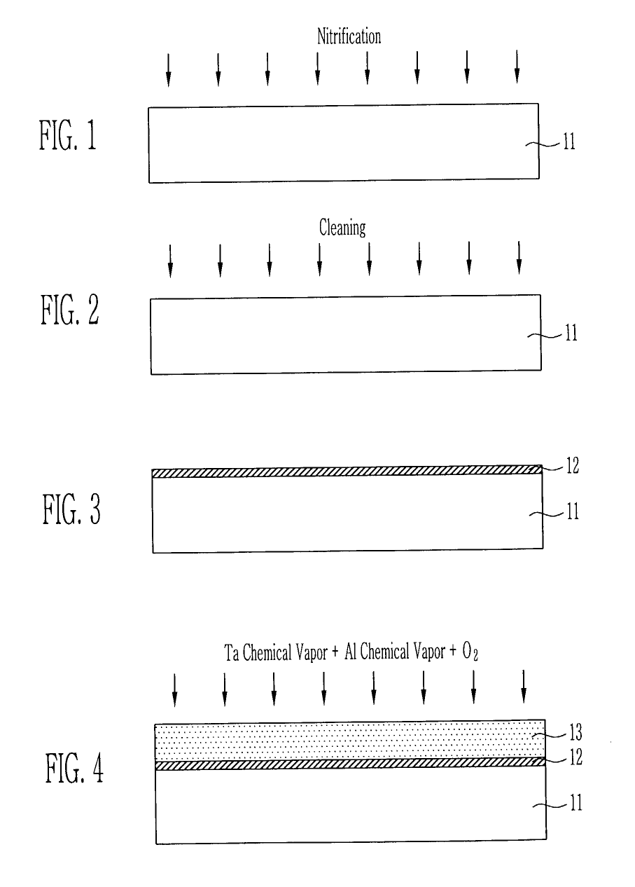

FIG. 1˜FIG. 7 are cross-sectional views of semiconductor devices for describing a method of manufacturing a tantalum pentaoxide-aluminum oxide (TA₂O₅—AL₂O₃) film according to a preferred embodiment of the present invention.

Referring now to FIG. 1, a lower layer 11 on which a dielectric film will be formed is formed by a process of manufacturing a semiconductor device. In order to prevent generation of a SiO₂ film having a bad film quality and a low dielectric constant of below 4 (four) at the interface between the lower layer 11 and the dielectric film upon a process of depositing the dielectric film and a subsequent annealing process, the surface of the lower layer 11 is experienced by nitrification treatment.

In the above, the surface nitrification treatment for the lower layer 11 includes several methods.

First, the surface nitrification treatment of the lower layer 11 is ex-situ performed using plasma under a NH₃ gas atmosphere or a N₂/H₂ gas atmosphere at a temperature of 200˜500° C. for 1˜10 minutes.

Second, the surface nitrification treatment of the lower layer 11 is in-situ or ex-situ performed by a rapid thermal nitrification (RTN) process under a NH₃ gas atmosphere at a temperature of 700˜900° C. for 1˜30 minutes.

Third, the surface nitrification treatment of the lower layer 11 is in-situ or ex-situ performed using a furnace under a NH₃ gas atmosphere at a temperature of 550˜800° C.

Referring now to FIG. 2, the lower layer 11 for which the nitrification treatment is performed is cleaned. The cleaning process is performed using a HF composition, a composition such as a NH₄OH solution or a H₂SO₄ solution, or the like. At this time, the HF composition is used to remove a native oxide film generated on the lower layer 11. Also, the composition such as the NH₄OH solution or the H₂SO₄ solution is used to improve the uniformity.

By reference to FIG. 3, in order to prevent generation of the SiO₂ film having a bad film quality and a low dielectric constant of below 4 (four) at the interface between the lower layer 11 and the dielectric film upon the process of depositing the dielectric film and a subsequent annealing process, a nitride film 12 of 5˜30 Å in thickness is formed on the surface of the lower layer 11.

Referring now to FIG. 4, an amorphous (Ta₂O₅)_{1-X}—(Al₂O₃)_{X} film 13 is formed by introducing a surface chemical reaction within a low pressure chemical vapor deposition (LPCVD) chamber using chemical vapor of a Ta component, chemical vapor of an Al component and an excess O₂ gas.

At this time, the chemical vapor of the Ta component is obtained by evaporating a Ta precursor of a given amount that is supplied to an evaporator or an evaporation tube through a flow controller such as a mass flow controller (MFC).

The Ta precursor from which the chemical vapor of the Ta component is obtained has several kinds. At this time, the evaporating temperature and evaporating condition are different a little depending on the kind of the Ta precursor. In case that the Ta precursor is tantalum ethylate (Ta(OC₂H₅)₅), the evaporating temperature ranges from 140 to 200° C.

The chemical vapor of the Al component is obtained by evaporating an Al precursor of a given amount that is supplied to the evaporator or the evaporation tube through the flow controller such as the mass flow controller (MFC). The Al precursor from which the chemical vapor of the Al component is obtained has several kinds. At this time, the evaporating temperature and evaporating condition are different a little depending on the kind of the Al precursor. In case that the Al precursor is aluminum ethylate (Al(OC₂H₅)₃), the evaporating temperature ranges from 150 to 250° C.

The chemical vapor of the Ta component and the chemical vapor of the Al component are surface-chemical-reacted within the LPCVD chamber under the excess O₂ gas being a reaction gas at the mole ratio of Al/Ta=0.01˜0.5, thus producing the amorphous (Ta₂O₅)_{1-X}—(Al₂O₃)_{X} film 13.

Referring now to FIG. 5, a low temperature annealing process is performed, in order to effectively oxidize the substitution Ta atom being the oxygen vacancy atom that exists within the amorphous (Ta₂O₅)_{1-X}—(Al₂O₃)_{X} film 13 and the carbon compositions such as C, CH₄, C₂H₄, or the like being a reaction byproduct and to increase the coupling force so that an unstable stoichiometry of the Ta₂O₅ film can be stabilized.

In the above, the low temperature annealing process is in-situ performed using plasma or UV-O₃ at a temperature ranging from 300 to 600° C. The plasma low temperature annealing process is performed under a N₂O gas atmosphere or an O₂ gas atmosphere.

Referring to FIG. 6, a high temperature process is performed in order to remove an impurity such as a carbon composition that exists within the amorphous (Ta₂O₅)_{1-X}—(Al₂O₃)_{X} film 13 and to crystallize the amorphous (Ta₂O₅)_{1-X}—(Al₂O₃)_{X} film 13. Due to this, a crystal (Ta₂O₅)_{1-X}—(Al₂O₃)_{X} film 130 having a higher dielectric constant and more stable stoichiometry than the existing Ta₂O₅ film is obtained.

In the above, the high temperature annealing process is in-situ or ex-situ performed using a furnace or a rapid thermal process (RTP) under the N₂O gas, the O₂ gas or the N₂ gas atmosphere at a temperature of 700˜950° C. for 5˜60 minutes.

By reference to FIG. 7, in order to prevent generation of the SiO₂ film having a bad film quality and a low dielectric constant of below 4 at the interface between an upper layer (not shown) to be formed in a subsequent process and the crystal (Ta₂O₅)_{1-X}—(Al₂O₃)_{X} film 130, the surface of the crystal (Ta₂O₅)_{1-X}—(Al₂O₃)_{X} film 130 is experienced by nitrification treatment.

In the above, the surface nitrification treatment of the crystal (Ta₂O₅)_{1-X}—(Al₂O₃)_{X} film 130 is in-situ or ex-situ performed using plasma under the NH₃ gas atmosphere or the N₂/H₂ gas atmosphere at a temperature ranging from 200 to 500° C. Further, in order to completely crystalline portions left without being crystallized even after the high temperature annealing process, the surface nitrification treatment of the crystal (Ta₂O₅)_{1-X}—(Al₂O₃)_{X} film 130 may be in-situ or ex-situ performed using the furnace or the rapid thermal nitrification (RTN) under the NH₃ gas atmosphere at a temperature of 550˜900° C.

Though the method of manufacturing the (Ta₂O₅)_{1-X}—(Al₂O₃)_{X} film of the present invention that was explained by reference to FIG. 1˜FIG. 7 is the preferred embodiment of the present invention, it should be noted that one of the surface nitrification treatment step of the lower layer 11 and the step of forming the nitride film 12, which are performed in order to prevent generation of the SiO₂ film having a bad film quality and a low dielectric constant of below 4 (four) at the interface between the lower layer 11 and the (Ta₂O₅)_{1-X}—(Al₂O₃)_{X} film 130, may be omitted.

Characteristics of the (Ta₂O₅)_{1-X}—(Al₂O₃)_{X} film manufactured by the above method will be below described.

According to the present invention, when the amorphous Ta₂O₅ film is deposited using the LPCVD method, the (Ta₂O₅)_{1-X}—(Al₂O₃)_{X} (0.01≦x≦0.5) film having a high dielectric constant can be obtained by adding an Al component through a surface chemical reaction differently from the existing method. The dielectric constant of the (Ta₂O₅)_{1-X}—(Al₂O₃)_{X} film is about 40 (forty). In particular, the (Ta₂O₅)_{1-X}—(Al₂O₃)_{X} film is stable in structure since Al₂O₃ of a perovskite type structure is covalently coupled with Ta₂O₅ within the film.

Meanwhile, the substitution Ta atom of the oxygen vacancy state may exist locally within the (Ta₂O₅)_{1-X}—(Al₂O₃)_{X} film due to an unstable composition of Ta₂O₅ itself. Though the number of the oxygen vacancy of the (Ta₂O₅)_{1-X}—(Al₂O₃)_{X} film may be different depending on the degree of coupling with the contents of the Al₂O₃ dielectric component, the number of the oxygen vacancy becomes further smaller than when it exists as a pure Ta₂O₅ film. Therefore, the leakage current becomes relatively low compared to the Ta₂O₅ film when the (Ta₂O₅)_{1-X}—(Al₂O₃)_{X} film is formed.

Further, in the present invention, in order to prevent generation of the oxide film of a low dielectric constant at the interface between the lower layer and the (Ta₂O₅)_{1-X}—(Al₂O₃)_{X} film during the high temperature annealing process after the (Ta₂O₅)_{1-X}—(Al₂O₃)_{X} film is deposited, a surface nitrification technology using plasma and a rapid thermal process (RTP) is applied to a pre-treatment process for depositing the (Ta₂O₅)_{1-X}—(Al₂O₃)_{X} film. Therefore, the equivalent oxide film thickness (Tox) of the (Ta₂O₅)_{1-X}—(Al₂O₃)_{X} film can be controlled by prohibiting oxidization of the interface. In addition, it is possible to prevent generation of the leakage current due to formation of the unstable oxide film. Further, as volatile carbon compositions such as C, CH₄, C₂H₄, etc. existing as a reaction byproduct within the thin film and non-coupled carbon (C) oxidized by an active oxygen are removed in a volatile gas state such as CO or CO₂ by means of the high temperature annealing process under the N₂O atmosphere, the leakage current due to the impurity within the film can be effectively prevented. In particular, the amorphous (Ta₂O₅)_{1-X}—(Al₂O₃)_{X} film is crystallized by the high temperature annealing process. Due to this, the dielectric constant can be significantly improved since the film becomes dense. As a result, as the film quality is significantly improved when the above deposition pre-treatment process and the subsequent annealing process are used, the (Ta₂O₅)_{1-X}—(Al₂O₃)_{X} film having a good dielectric characteristic can be obtained.

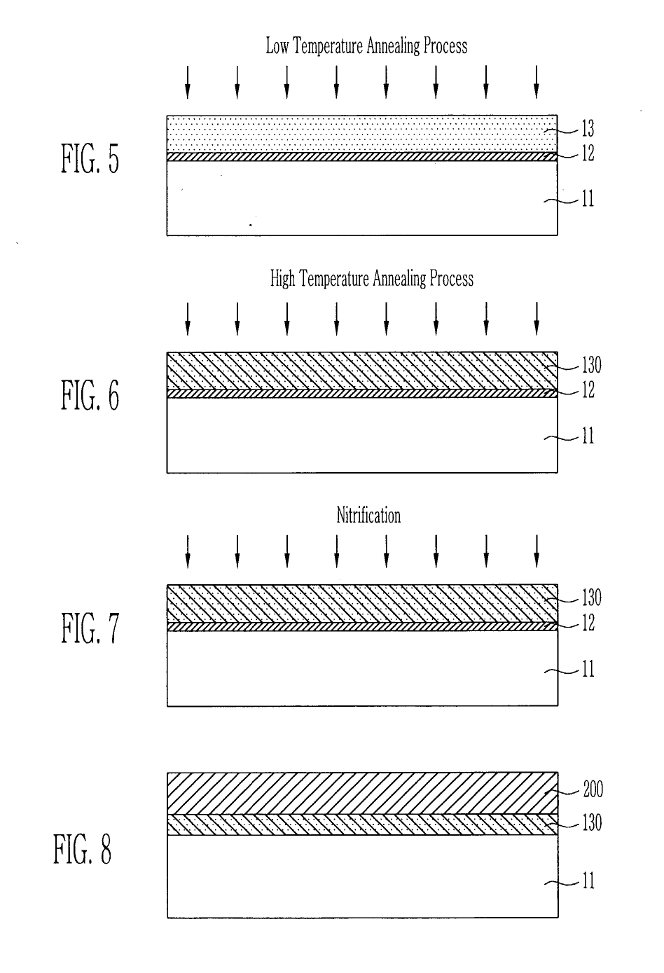

In case that the (Ta₂O₅)_{1-X}—(Al₂O₃)_{X} film having these characteristics is applied to all the semiconductor devices requiring the dielectric film, it is possible to improve reliability and an electrical characteristic of the device and to implement a higher level of integration in the device. FIG. 8 shows a cross-sectional view of the semiconductor device for explaining a case that the (Ta₂O₅)_{1-X}—(Al₂O₃)_{X} film manufactured by the present invention is applied to various semiconductor devices.

In case that the structure shown in FIG. 8 is a cell transistor of a flash memory, the lower layer 11 serves as a floating gate, the (Ta₂O₅)_{1-X}—(Al₂O₃)_{X} film 130 serves as a dielectric film and the upper layer 200 serves as a control gate. The lower layer 11 being the floating gate and the upper layer 200 being the control gate may be formed using doped polysilicon or at least one of metal-series materials such as TaN, W, WN, WSi, Ru, RuO₂, Ir, IrO₂, Pt, TiN, or the like. In case that the upper layer 200 being the control gate is formed using the metal-series material, the upper layer 200 may have a stack structure in which the metal-series material is deposited in thickness of 100˜600 Å and doped polysilicon as a buffer layer is then deposited on the metal-series material in order to prevent degradation in the electrical characteristic of the cell transistor.

In case that the structure shown in FIG. 8 is a transistor of the DRAM, the lower layer 11 serves as a semiconductor substrate, the (Ta₂O₅)_{1-X}—(Al₂O₃)_{X} film 130 serves as a gate insulating film and the upper layer 200 serves as a gate electrode. The upper layer 200 being the gate electrode may be formed using doped polysilicon or at least one of the metal-series materials such as TaN, W, WN, WSi, Ru, RuO₂, Ir, IrO₂, Pt, TiN, or the like. In case that the upper layer 200 being the control gate is formed using the metal-series material, the upper layer 200 may have a stack structure in which the metal-series material is deposited in thickness of 100˜600 Å and doped polysilicon as the buffer layer is then deposited on the metal-series material in order to prevent degradation in the electrical characteristic of the transistor.

In case that the structure shown in FIG. 8 is a capacitor of the DRAM, the lower layer 11 serves as a lower electrode, the (Ta₂O₅)_{1-X}—(Al₂O₃)_{X} film 130 serves as a capacitor dielectric film and the upper layer 200 serves as an upper electrode. The lower layer 11 being the upper electrode and the upper layer 200 being the lower electrode may be formed using doped polysilicon or at least one of the metal-series materials such as TaN, W, WN, WSi, Ru, RuO₂, Ir, IrO₂, Pt, TiN, or the like. In case that the upper layer 200 being the upper electrode is formed using the metal-series material, the upper layer 200 may have a stack structure in which the metal-series material is deposited in thickness of 100˜600 Å and doped polysilicon as a buffer layer is then deposited on the metal-series material in order to prevent degradation in the electrical characteristic of the capacitor.

The (Ta₂O₅)_{1-X}—(Al₂O₃)_{X} film 130 manufactured by the present invention can be applied all the semiconductor devices requiring films having a high dielectric constant in addition to the cell transistor of the flash memory, the transistor of DRAM and the capacitor of DRAM.

As mentioned above, according to the present invention, the (Ta₂O₅)_{1-X}—(Al₂O₃)_{X} film having a high dielectric constant and a stable stoichoimetry can be obtained. Therefore, the present invention has an advantage that it can accomplish a higher charge capacitance than the charge capacitance of the cell transistor of the flash memory or the capacitor of the DRAM using the conventional ONO dielectric film having a dielectric constant of about 4˜5 and the conventional Ta₂O₅ dielectric film having a dielectric constant of about 25.

Further, a module of a complicate 3D structure for increasing the area of the lower layer that stores electric charges is not required in the (Ta₂O₅)_{1-X}—(Al₂O₃)_{X} film since the film has a high dielectric constant. Due to this, it is possible to obtain a sufficient charge capacitance even with the stack structure the process for forming the lower layer module of which is simple. Therefore, the present invention has advantages that it can reduce the number of unit process and reduce the production cost.

In addition, Al₂O₃ having a good mechanical strength in the (Ta₂O₅)_{1-X}—(Al₂O₃)_{X} film has a perovskite structure (ABO₃ structure) and is covalently coupled with Ta₂O₅ Thus, the (Ta₂O₅)_{1-X}—(Al₂O₃)_{X} film has a good mechanical-electrical strength compared to a case that the (Ta₂O₅)_{1-X}—(Al₂O₃)_{X} film exists as Ta₂O₅ itself. Further, the (Ta₂O₅)_{1-X}—(Al₂O₃)_{X} film is insensitive to an electrical shock from the outside since the (Ta₂O₅)_{1-X}—(Al₂O₃)_{X} film is stable in structure. In addition, the (Ta₂O₅)_{1-X}—(Al₂O₃)_{X} film has a better electrical characteristic than a device using the Ta₂O₅ dielectric film. since the (Ta₂O₅)_{1-X}—(Al₂O₃)_{X} film has a low leakage current

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed is:

1. A method of manufacturing a tantalum pentaoxide-aluminum oxide (TA₂O₅—AL₂O₃) film, comprising the steps of:
forming a lower layer;
forming an amorphous (Ta₂O₅)_{1-X}—(Al₂O₃)_{X} film on the lower layer using chemical vapor of a Ta component, chemical vapor of an Al component and an excess O₂ gas; and
annealing the amorphous (Ta₂O₅)_{1-X}—(Al₂O₃)_{X} film to form a crystal (Ta₂O₅)_{1-X}—(Al₂O₃)_{X} film.

2. The method as claimed in claim 1, further comprising the step of:
before the amorphous (Ta₂O₅)_{1-X}—(Al₂O₃)_{X} film is formed,
performing nitrification treatment on the surface of the lower layer; and
cleaning the nitrification treated lower layer.

3. The method as claimed in claim 2, wherein the surface nitrification treatment of the lower layer is performed using plasma under a NH₃ gas atmosphere or a N₂/H₂ gas atmosphere at a temperature of 200˜500° C. for 1˜10 minutes.

4. The method as claimed in claim 2, wherein the surface nitrification treatment of the lower layer is performed using rapid thermal nitrification (RTN) under a NH₃ gas atmosphere at a temperature of 700˜900° C. for 1˜30 minutes.

5. The method as claimed in claim 2, wherein the surface nitrification treatment of the lower layer is performed using a furnace under a NH₃ gas atmosphere at a temperature of 550˜800° C.

6. The method as claimed in claim 2, wherein the cleaning process is performed using a HF composition or compositions such as a NH₄OH solution or a H₂SO₄ solution.

7. The method as claimed in claim 1, further comprising the step of forming a nitride film on the lower layer before the amorphous (Ta₂O₅)_{1-X}—(Al₂O₃)_{X} film is formed.

8. The method as claimed in claim 7, wherein the nitride film is formed in thickness of 5˜30 Å.

9. The method as claimed in claim 1, wherein the chemical vapor of the Ta component is obtained by evaporating a Ta precursor of a given amount supplied to an evaporator or an evaporating tube through a flow controller such as a mass flow controller (MFC).

10. The method as claimed in claim 9, wherein the Ta precursor is Ta(OC₂H₅)₅ and the chemical vapor of the Ta component is obtained by evaporating Ta(OC₂H₅)₅ at a temperature ranging from 140 to 200° C.

11. The method as claimed in claim 1, wherein the chemical vapor of the Al component is obtained by evaporating an Al precursor of a given amount supplied to an evaporator or an evaporating tube through a flow controller such as a mass flow controller (MFC).

12. The method as claimed in claim 11, wherein the Al precursor is Al(OC₂H₅)₃ and the chemical vapor of the Al component is obtained by evaporating Al(OC₂H₅)₃ at a temperature ranging from 150 to 250° C.

13. The method as claimed in claim 1, wherein the amorphous (Ta₂O₅)_{1-X}—(Al₂O₃)_{X} film is formed by introducing a surface chemical reaction within a low pressure chemical vapor deposition (LPCVD) chamber using an excess O₂ gas being a reaction gas at the mole ratio of Al/Ta=0.01˜0.5 in a chemical vapor of a Ta component and a chemical vapor of an Al component.

14. The method as claimed in claim 1, wherein the annealing process includes sequentially performing a low temperature annealing process and a high temperature annealing process.

15. The method as claimed in claim 14, wherein the low temperature annealing process is performed using plasma under a N₂O gas atmosphere or an O₂ gas atmosphere at a temperature of 300˜600° C.

16. The method as claimed in claim 14, wherein the low temperature annealing process is performed using UV-O₃ at a temperature of 300˜600° C.

17. The method as claimed in claim 14, wherein the high temperature annealing process is performed using a furnace under a N₂O gas, an O₂ gas or a N₂ gas atmosphere at a temperature ranging from 700 to 950° C. for 5˜60 minutes.

18. The method as claimed in claim 14, wherein the high temperature annealing process is performed using a rapid thermal process (RTP) under a N₂O gas, an O₂ gas or a N₂ gas atmosphere at a temperature ranging from 700 to 950° C.

19. The method as claimed in claim 1, further comprising the step of performing nitrification treatment for the surface of the crystal (Ta₂O₅)_{1-X}—(Al₂O₃)_{X} film.

20. The method as claimed in claim 19, wherein the surface nitrification treatment of the crystal (Ta₂O₅)_{1-X}—(Al₂O₃)_{X} film is performed using plasma under a NH₃ gas atmosphere or a N₂/H₂ gas atmosphere at a temperature of 200˜500° C.

21. The method as claimed in claim 19, wherein the surface nitrification treatment of the crystal (Ta₂O₅)_{1-X}—(Al₂O₃)_{X} film is performed using a furnace or rapid thermal nitrification (RTN) under a NH₃ gas atmosphere at a temperature of 550˜900° C.

22. A cell transistor of a flash memory having a structure in which a dielectric film is formed between a floating gate and a control gate, being characterized in that the dielectric film is formed of the crystal (Ta₂O₅)_{1-X}—(Al₂O₃)_{X} film that is manufactured by the method cited in claim 1.

23. The cell transistor as claimed in claim 22, wherein the floating gate and the control gate are formed using doped polysilicon or at least one of metal-series materials such as TaN, W, WN, WSi, Ru, RuO₂, Ir, IrO₂, Pt and TiN.

24. A transistor of a DRAM having a structure in which a gate insulating film is formed between a semiconductor substrate and a gate electrode, being characterized in that the gate insulating film is formed of the crystal (Ta₂O₅)_{1-X}—(Al₂O₃)_{X} film that is manufactured by the method cited in claim 1.

25. The transistor as claimed in claim 24, wherein the gate insulating film is formed using doped polysilicon or at least one of metal-series materials such as TaN, W, WN, WSi, Ru, RuO₂, Ir, IrO₂, Pt and TiN.

26. A capacitor of a DRAM having a structure in which a dielectric film is formed between a lower electrode and an upper electrode, being characterized in that the dielectric film is formed of the crystal (Ta₂O₅)_{1-X}—(Al₂O₃)_{X} film that is manufactured by the method cited in claim 1.

27. The capacitor as claimed in claim 26, wherein the upper electrode and the lower electrode are formed using doped polysilicon or at least one of metal-series materials such as TaN, W, WN, WSi, Ru, RuO₂, Ir, IrO₂, Pt and TiN.
